(19) United States
(12) Patent Application Publication
(10) Pub. No.: US 2016/0005681 A1
(43) Pub. Date: Jan. 7, 2016

(54) SEMICONDUCTOR PACKAGE AND METHOD OF MANUFACTURING THE SAME

(71) Applicant: Kabushiki Kaisha Toshiba, Minato-ku (JP)

(72) Inventors: Atsushi KUROSU, Itabashi (JP); Tetsuya YOKOI, Toshima (JP)

(73) Assignee: Kabushiki Kaisha Toshiba, Minato-ku (JP)

(21) Appl. No.: 14/744,278

(22) Filed: Jun. 19, 2015

(30) Foreign Application Priority Data
Jul. 7, 2014 (JP) 2014-139666

(51) Int. Cl. H01L 23/495; H01L 21/48; H01L 21/78

(52) U.S. Cl. CPC H01L 23/49568; H01L 23/4952; H01L 21/78; H01L 21/4842; H01L 21/4875

(57) ABSTRACT

A semiconductor package includes a frame formed of a metal and including multiple grooves formed in a surface, and, a semiconductor chip connected with the surface of the frame. A semiconductor device includes the semiconductor chip, and a base frame formed of copper and bonded to the bottom face of the semiconductor chip. In addition, the semiconductor chip and the base frame are bonded together by surface activation.

### CROSS REFERENCE TO RELATED APPLICATIONS

This application is based upon and claims the benefit of priority from the prior Japanese Patent Application No. 2014-139666 filed in Japan on Jul. 7, 2014; the entire contents of which are incorporated herein by reference.

### FIELD

Embodiments described herein relate generally to a semiconductor package and a method of manufacturing the same.

### BACKGROUND

In recent years, because of multifunction designing of semiconductor devices and improvement of operation speed thereof, the amount of heat generated by semiconductor devices are increasing. Hence, various devisals to efficiently dissipate heat from semiconductor devices are applied to a wiring board on which such semiconductor devices are mounted.

### BRIEF DESCRIPTION OF THE DRAWINGS

FIG. 1 is a perspective view illustrating a semiconductor package according to an embodiment;

FIG. 2 is a perspective view illustrating the semiconductor package according to the embodiment;

FIG. 3 is a cross-sectional view illustrating the semiconductor package according to the embodiment;

FIG. 4 is a plan view illustrating a wafer;

FIG. 5 is a plan view illustrating a copper plate;

FIG. 6 is a diagram for explaining a bonding process of the wafer with the copper plate;

FIG. 7 is a diagram for explaining the bonding process of the wafer with the copper plate;

FIG. 8 is a diagram illustrating a positional relationship between a circuit pattern formed on the wafer and a groove formed in the copper plate;

FIG. 9 is a diagram for explaining a dicing process of semiconductor devices;

FIG. 10 is a diagram for explaining the dicing process of the semiconductor devices;

FIG. 11 is a diagram for explaining the dicing process of the semiconductor devices;

FIG. 12 is a perspective view illustrating the semiconductor device;

FIG. 13 is a diagram for explaining a wire bonding process for the semiconductor device;

FIG. 14 is a diagram for explaining a molding process for the semiconductor device; and

FIG. 15 is a diagram for explaining a lead-terminal creating process for the semiconductor package.

### DETAILED DESCRIPTION

A semiconductor package according to this embodiment includes a frame and a semiconductor chip. The frame is formed of a metal, and multiple grooves are formed in the surface of this frame. The semiconductor chip is connected with the surface of the frame.

A method of manufacturing the semiconductor package according to this embodiment is a semiconductor package manufacturing method, and the method includes steps of bonding, by surface activation, a silicon substrate to a surface of a metal plate in which multiple grooves are formed, and cutting the silicon substrate together with the metal plate, and cutting out a semiconductor device.

An embodiment of the present disclosure will be explained below with reference to the figures. The explanation will be given with reference to an XYZ coordinate system that includes X, Y, and Z axes orthogonal to one another.

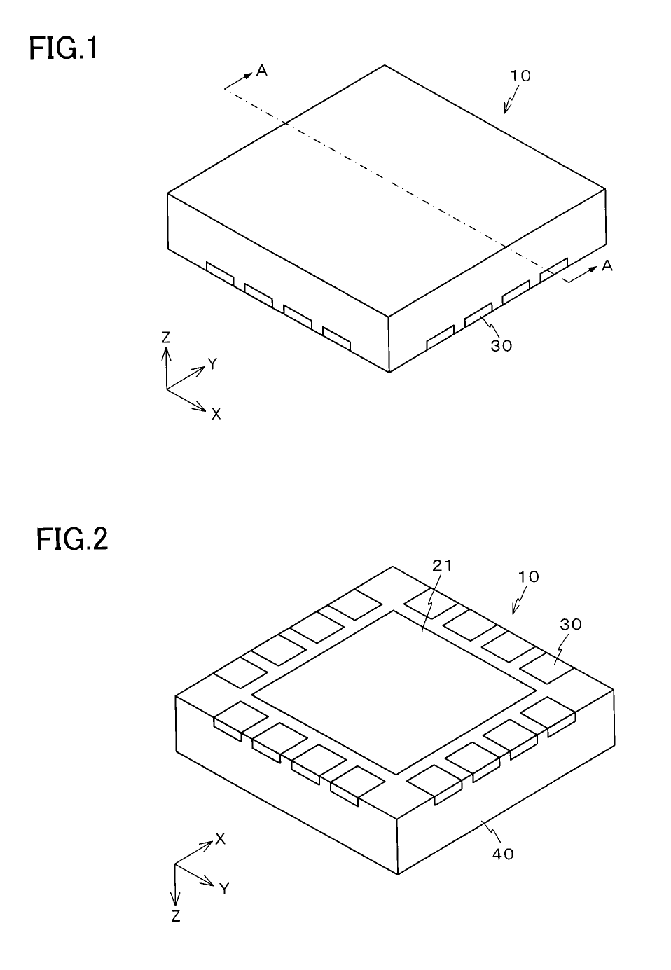

FIG. 1 and FIG. 2 are each a perspective view illustrating an example semiconductor package 10 according to this embodiment. The semiconductor package 10 is a QFN (Quad For Non-Lead Package) type semiconductor package. This semiconductor package 10 is formed in a square shape which has a side of substantially 10 mm, and which has a thickness of substantially 3 mm.

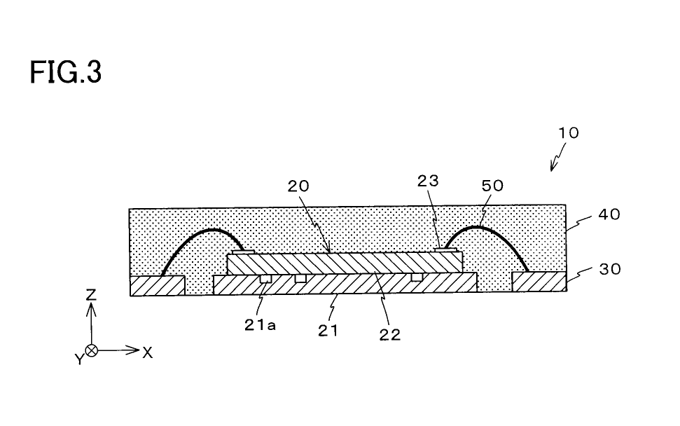

FIG. 3 is a diagram illustrating an A-A cross section of the semiconductor package 10 in FIG. 1. As illustrated in FIG. 3, the semiconductor package 10 includes a semiconductor device 20, lead terminals 30 disposed around the semiconductor device 20, bonding wires 50 that connect the semiconductor device 20 with the respective lead terminals 30, a resin 40 that molds the semiconductor device 20 and the lead terminals 30, and the like.

The semiconductor device 20 includes a base frame 21, and a semiconductor chip 22 provided on the top face of the base frame 21.

The base frame 21 is formed of copper (Cu), and is a square member which has a thickness of substantially 0.2 mm and has a side of substantially 4 mm. Grooves 21a are formed in the top face (a surface at +Z side) of the base frame 21. Grooves 21a form an angle of 45 degrees relative to the X axis and the Y axis. The width and depth of this groove 21a are substantially 0.1 mm. The bottom face (a surface at −Z side) of the base frame 21 is exposed from the resin 40.

The semiconductor chip 22 is formed of silicon (Si), and is a square member which has a thickness of substantially 0.3 mm and has a side of substantially 4 mm. A micropattern is formed on the top face of the semiconductor chip 22 by lithography. In addition, electrode pads 23 are formed on the top face of the semiconductor chip 22 along the outer circumference. According to the semiconductor package 10 of this embodiment, 16 electrode pads 23 are formed on the top face of the semiconductor chip 22.

The semiconductor chip 22 has the bottom face bonded to the top face of the base frame 21, thereby being integrated with the base frame 21. The bonding of the base frame 21 with the semiconductor chip 22 is performed by surface activation to be discussed later.

The lead terminals 30 are each a square terminal which has a thickness of 0.2 mm, and has a side of substantially 0.5 mm. As illustrated in FIG. 2, the lead terminals 30 are disposed so as to surround the base frame 21. The semiconductor package 10 according to this embodiment has 16 lead terminals 30 around the base frame 21 at the pitch of substantially 0.5 mm.

Returning to FIG. 3, the bonding wires 50 are each formed of gold (Au), copper (Cu) or aluminum (Al), and are a wire having a diameter of substantially 30 μm. The bonding wire 50 has one end connected to the top face of the electrode pad 23 provided on the semiconductor chip 22, and has the other end connected to the top face of the lead terminal 30. The bonding wire 50 causes the semiconductor chip 22 and the respective lead terminals 30 to be electrically connected with each other.

The semiconductor device 20, the lead terminals 30, and the bonding wires 50 are molded by the resin 40. Accordingly, the semiconductor device 20, the lead terminals 30, and the bonding wires 50 are integrated one another with the semiconductor device 20, the lead terminals 30, and the bonding wires 50 being positioned one another.

Next, the method of manufacturing the above semiconductor package 10 will be explained. First, a circular wafer is cut out from a cylindrical ingot formed of mono-crystal silicon. Next, the wafer is heated under an oxygen-silicon gas atmosphere. Hence, an oxide film is formed on the surface of the wafer.

Next, a photoresist is spin coated to the surface of the wafer formed with the oxide film. Accordingly, a photoresist layer that covers the oxide film is formed on the surface of the wafer.

Subsequently, using an exposure system, the photoresist is exposed. Next, a development process is performed on the photoresist. Hence, the photoresist is patterned.

Subsequently, after the oxide film exposed from the photoresist is etched, the photoresist is eliminated. Hence, the oxide film is patterned.

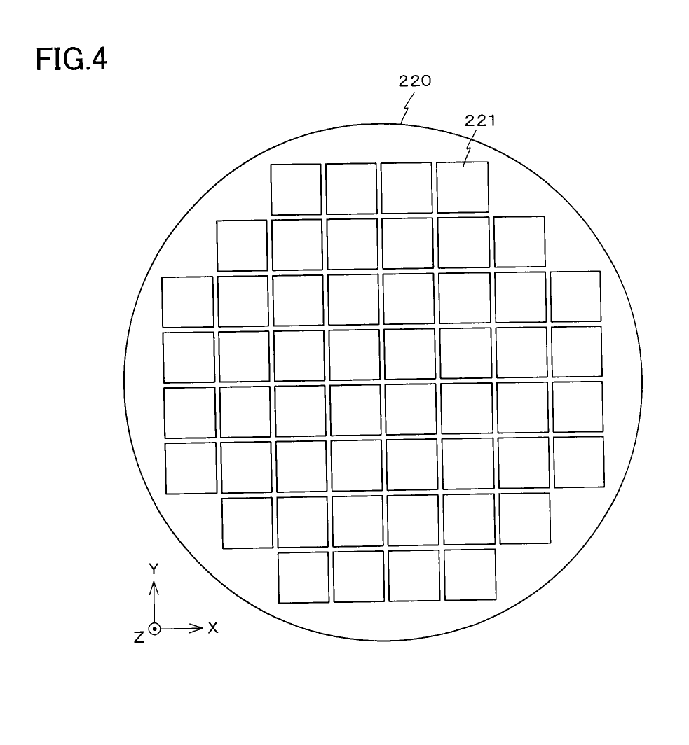

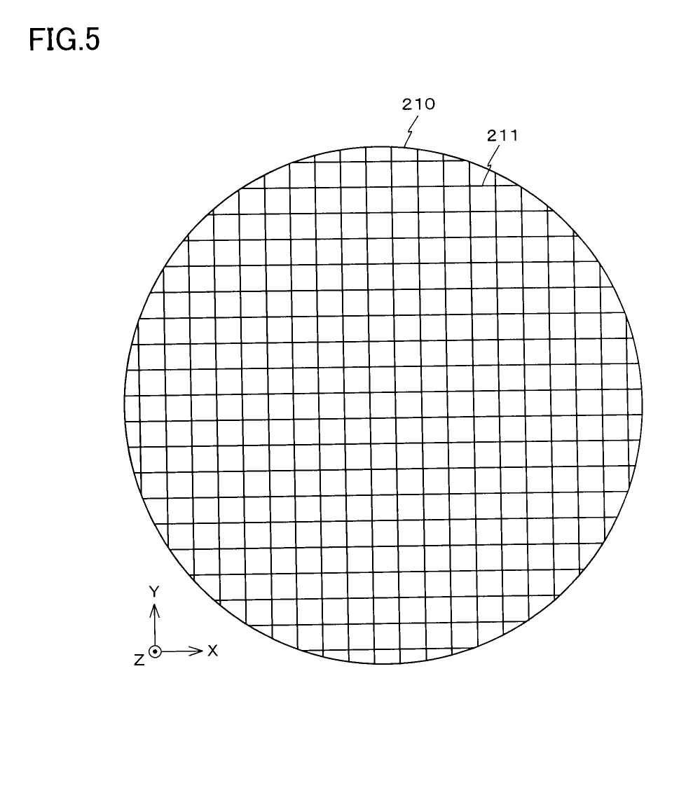

Next, the wafer is heated, and boron and phosphorous are doped in the oxide film formed on the surface of the wafer. Subsequently, aluminum, etc., is deposited on the surface of the oxide film. Hence, a wafer that has a circuit pattern formed on the surface thereof is finished. FIG. 4 is a diagram illustrating a wafer 220 manufactured through the above photolithography process.

As illustrated in FIG. 4, the wafer 220 has square circuit patterns 221 formed in the X-axis direction and in the Y-axis direction at an equal pitch. In this embodiment, as an example, 52 circuit patterns are formed on the surface of the wafer 220.

Next, as illustrated in FIG. 5, a circular copper plate 210 which has as thickness of 0.2 mm and which has a diameter consistent with or slightly smaller than that of wafer 220 is prepared. Grooves 211 in parallel with the X axis and grooves 211 in parallel with the Y axis are formed in a surface of the copper plate 210. The grooves 211 each have a width and a depth of 0.1 mm, and are formed at a pitch of 2 mm in the X-axis direction and in the Y-axis direction.

Next, after the bottom face of the wafer 220 is polished, the wafer 220 and the copper plate 210 are placed in, for example, a vacuum chamber. Subsequently, a vacuum atmosphere is formed around the wafer 220 and the copperplate 210.

Next, a sputter-etching process is performed on the bottom face of the wafer 220 and the top face of the copper plate 210 by ion beams or plasma of argon (Ar). Through the sputter-etching process, the oxide films, contaminated substances, etc., on the bottom face of the wafer 220 and on the top face of the copper plate 210 are removed. Consequently, the bottom face of the wafer 220 and the top face of the copper plate 210 are activated.

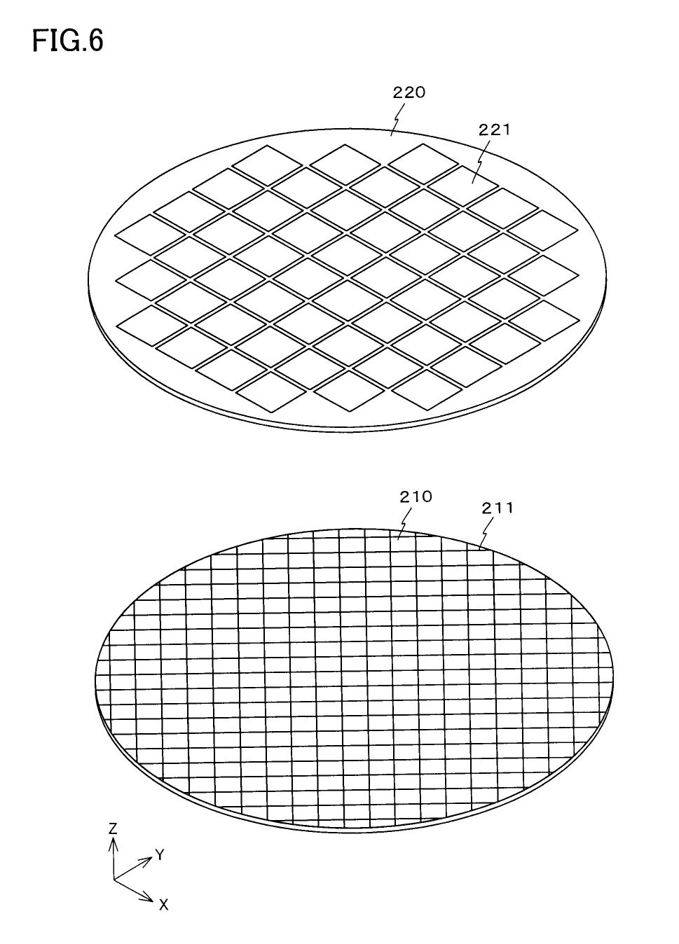

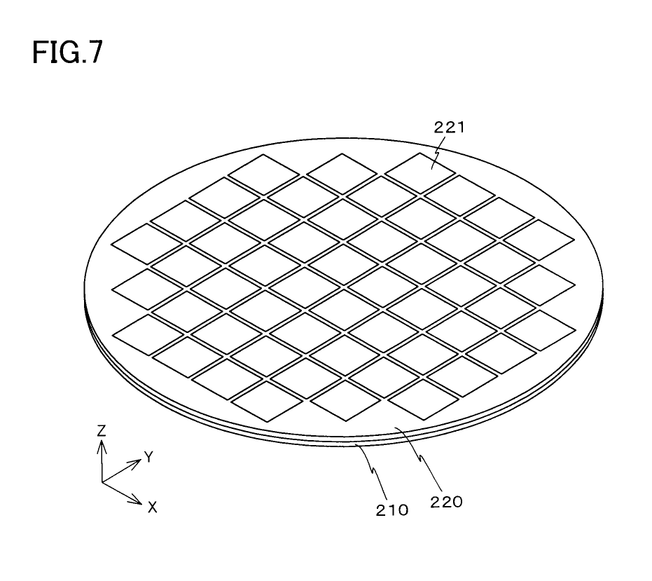

Subsequently, as illustrated in FIG. 6, the relative position of the wafer 220 and those of the circuit patterns 221 are adjusted in such a way that the direction of arrangement (X-axis direction or Y-axis direction) of the circuit patterns 221 formed on the wafer 220 forms an angle of 45 degrees relative to the grooves 211 formed in the copper plate 210. Next, as illustrated in FIG. 7, the bottom face of the wafer 220 is caused to be intimately in contact with the top face of the copper plate 210. Hence, although under the normal temperature condition, the bottom face of the wafer 220 and the top face of the copper plate 210 are firmly bonded together.

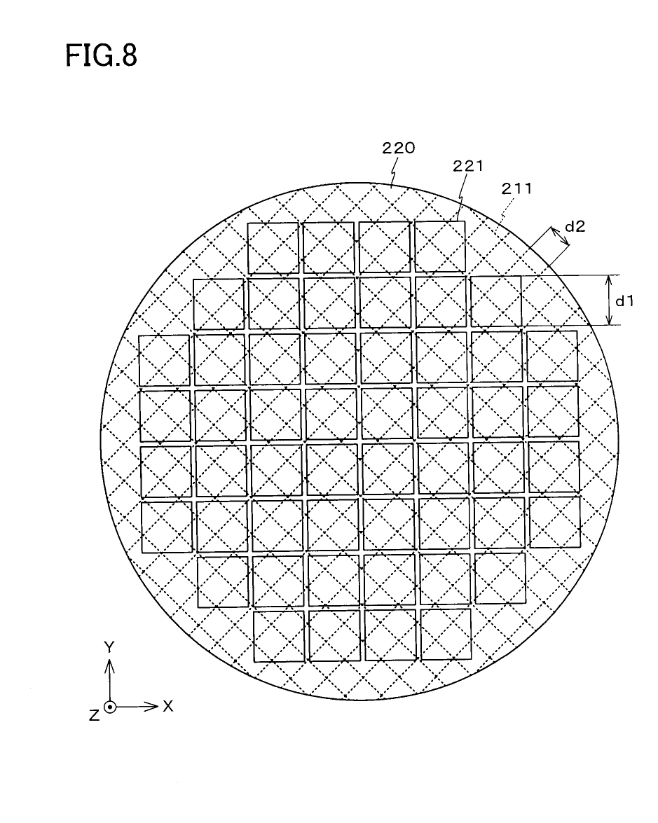

FIG. 8 is a diagram illustrating a positional relationship between the circuit pattern 221 formed on the wafer 220 and the groove 211 formed in the copper plate 210. As illustrated in FIG. 8, according to the semiconductor package 10, a length d1 of a side of the circuit pattern 221 formed on the wafer 220 is substantially 4 mm, while an arrangement pitch d2 of the grooves 211 formed in the copper plate 210 is substantially 2 mm. Hence, as illustrated in FIG. 8, a circuit pattern 221 overlaps with the multiple grooves 211.

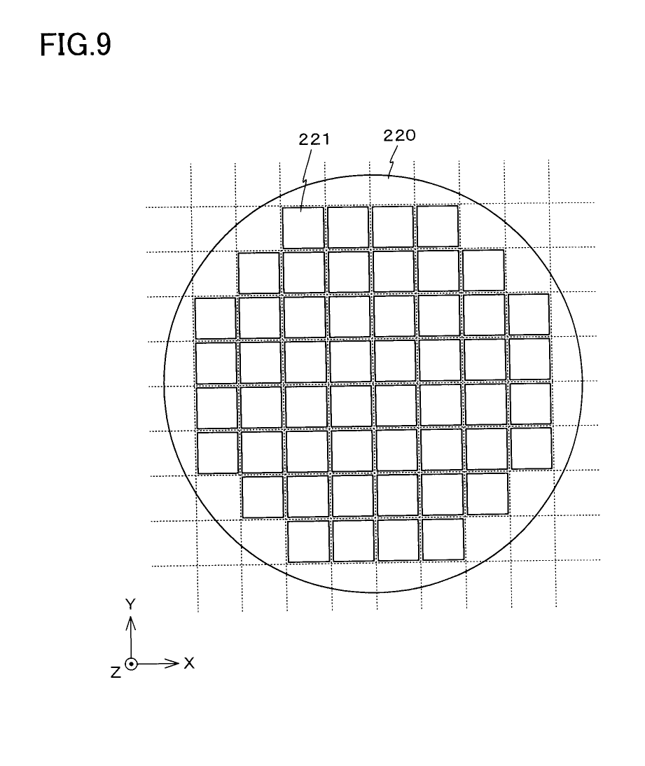

Next, the wafer 220 that has the bottom face bonded to the copper plate 210 is taken out from the vacuum chamber. Subsequently, as illustrated in FIG. 9, the wafer 220 and the copper plate 210 are cut along dashed lines in parallel with the respective sides of the circuit pattern 221. Blades with different thicknesses are applied to cut the wafer 220 and the copper plate 210, respectively.

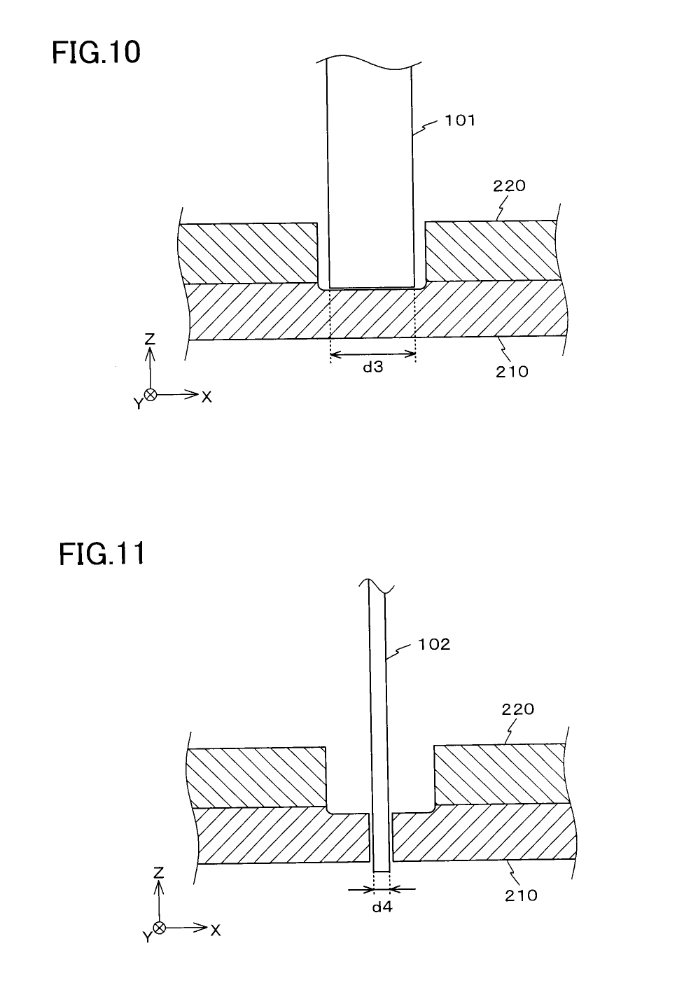

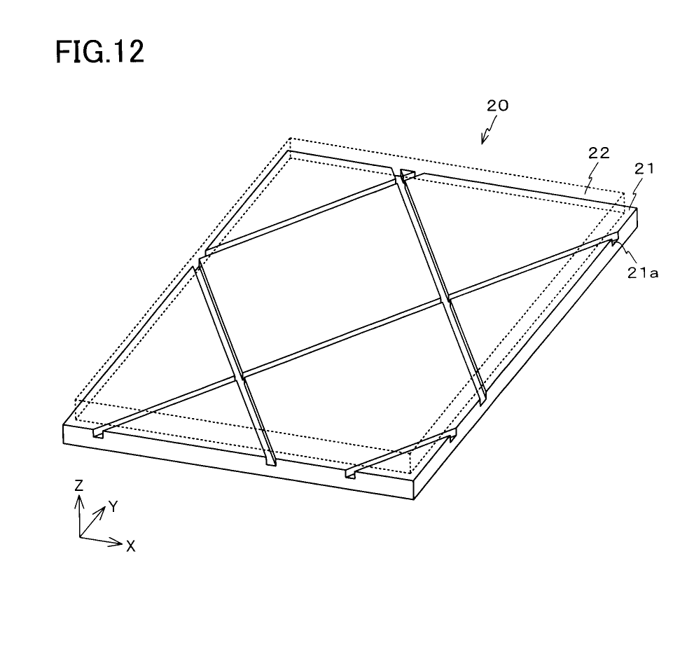

First, as illustrated in FIG. 10, only the wafer 220 is cut by a dicing blade 101 that has a width d3 of, for example, 30 μm. Next, as illustrated in FIG. 11, the copper plate 210 is cut by a dicing blade 102 that has a width d4 of, for example, 20 μm. Hence, the semiconductor device 20 illustrated in FIG. 3 is finished.

FIG. 12 is a perspective view of the semiconductor device 20. As illustrated in FIG. 12, the top face of the base frame 21 formed of the copper plate 210 is formed with the multiple grooves 21a that form an angle of 45 degrees relative to the outer circumference of the base frame 21. In addition, the semiconductor chip 22 is bonded to the top face of the base frame 21 in which the multiple grooves 21a are formed. Since the semiconductor chip 22 is in a rectangular shape, the outer circumference of the semiconductor chip 22 in parallel with the X-axis and the outer circumference in parallel with the Y-axis form an angle of 45 degrees relative to the grooved 21a.

As explained above, by cutting the wafer 220 and the copper plate 210 using the dicing blades 101, 102 with different thicknesses, respectively, the semiconductor chip 22 has a slightly smaller size than that of the base frame 21 that constructs the semiconductor device 20.

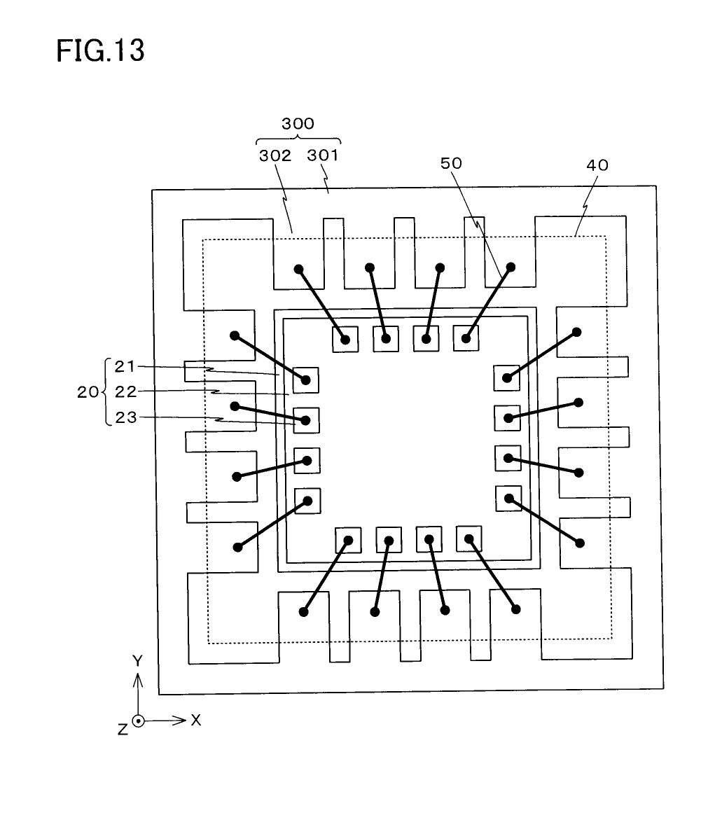

Next, as illustrated in FIG. 13, the semiconductor device 20 and a frame 300 are positioned with each other. The frame 300 is a member formed by cutting out a piece from a copper plate with a thickness of substantially 0.2 mm. The frame 300 includes two portions that are a frame portion 301 formed in a square shape, an 16 terminal portions 302 provided along the inner circumference of the frame portion 301 at an equal pitch.

After the frame 300 and the semiconductor device 20 are positioned with each other so as to have the center of the frame 300 aligned with the center of the semiconductor device 20, the respective electrode pads 23 provided on the semiconductor chip 22 that constructs the semiconductor device 20 are connected with the respective terminal portions 302 of the frame 300 by the respective bonding wires 50. As for the bonding of the bonding wires 50, a thermos-sonic type bonding technique is applicable.

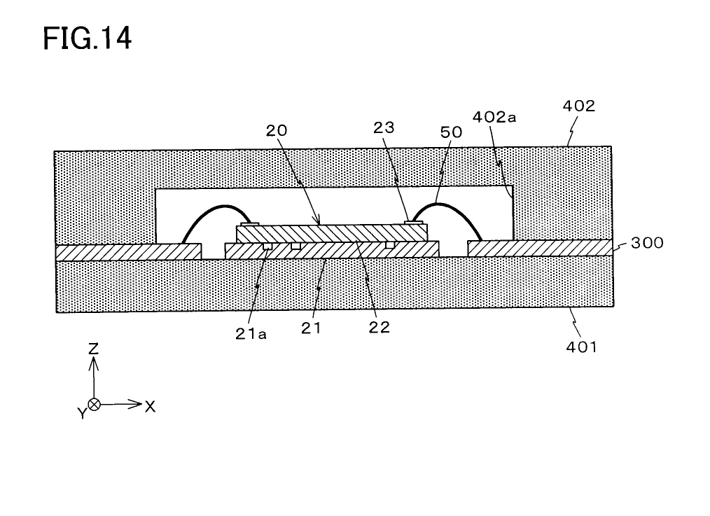

After the bonding of the bonding wires 50 completes, a molding process is performed on a part indicated by dashed lines in FIG. 13. In the molding process, first, as illustrated in FIG. 14, the semiconductor device 20 and the frame 300 are held between a mold form 401 with a flat top face, and a mold form 402 having a recess 402a formed in the bottom face. In this condition, the semiconductor device 20 is positioned inside the recess 402a formed in the mold form 402. Next, for example, a thermosetting epoxy-based resin 40 is filled in the recess 402a, and is cured. Hence, the semiconductor device 20 and the frame 300 are integrated with each other.

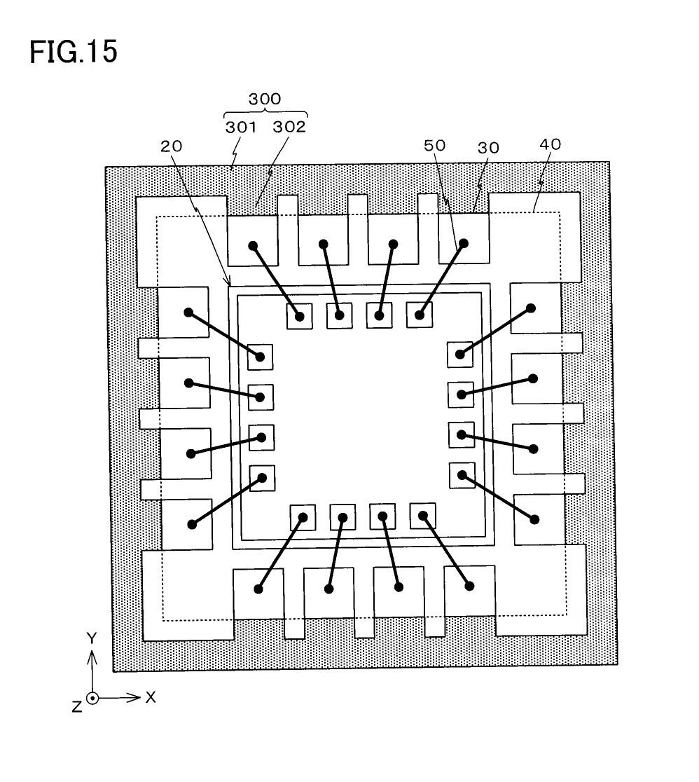

Subsequently, the mold forms 401, 402 are removed. In this condition, as is illustrated with a color in FIG. 15, a part of the frame portion 301 of the frame 300 and a part of the terminal portions 302 are protruding from the resin 40.

Next, portions of the frame portion 301 and terminal portions 302 protruding from the resin 40 are cut out, and burrs formed at respective side faces of the resin 40 are removed. Hence, the semiconductor package 10 illustrated in FIG. 3 are completed.

As explained above, according to this embodiment, the semiconductor device 20 includes the semiconductor chip 22, and the base frame 21 which is bonded to the bottom face of the semiconductor chip 22 and which is formed of copper. Hence, heat from the semiconductor chip 22 can be efficiently dissipated, thereby improving the operation reliability of the semiconductor device 20.

In this embodiment, the semiconductor device 20 is formed of the wafer 220 and the copper plate 210 which are bonded together by surface activation. Hence, when the wafer 220 and the copper plate 210 are bonded together, it is unnecessary to heat the wafer 220 and the copper plate 210. Therefore, thermal stress produced during the manufacturing of the semiconductor device 20 between the semiconductor chip 22 made from the wafer 220, and the base frame 21 made of the copper plate 210 can be suppressed. Accordingly, the highly reliable semiconductor device 20 with little deformation can be manufactured. In addition, during the manufacturing, peeling of the semiconductor chip 22 and of the base frame 21 originating from thermal stress can be suppressed, and thus the yield of the products can be improved.

In this embodiment, the grooves 21a are formed in the top face of the base frame 21. Hence, when the semiconductor device 20 is operated, even if the temperature of the semiconductor chip 22 that has a relatively small thermal expansion rate and that of the base frame 21 which has a relatively large thermal expansion rate rise, an increase of thermal stress produced between the semiconductor chip 22 and the base frame 21 can be suppressed. Accordingly, the reliability of the semiconductor device 20 can be improved.

In this embodiment, as is clear from FIG. 10 and FIG. 11, the wafer 220 is cut by the dicing blade 101. Next, the copper plate 210 is cut by the dicing blade 102 that has a thinner thickness (d4) than the thickness (d3) of the dicing blade 101. Accordingly, non-flatness is formed between the side face of the base frame 21 and the side face of the semiconductor chip 22 both constructing the semiconductor device 20. Hence, the contact area of the semiconductor device 20 with the resin 40 increases. Therefore, adhesion between the semiconductor device 20 and the resin 40 can be improved by an anchor effect.

In this embodiment, as illustrated in FIG. 8, the relative position of the wafer 220 and those of the circuit patterns 221 are adjusted in such a way that the arrangement direction (X-axis direction or Y-axis direction) of the circuit patterns 221 formed on the wafer 220 forms an angle of 45 degrees relative to the grooves 211 formed in the copper plate 210. Hence, when the copper plate 210 is cut by the dicing blade 102, the dicing blade 102 and the groove 211 intersect with each other. Consequently, the dicing blade 102 does not become in parallel with the groove 211 and is not disturbed by the groove. Accordingly, the copper plate 210 can be cut precisely.

Although the embodiment of the present disclosure was explained above, the present disclosure is not limited to the above embodiment. For example, in the above embodiment, the explanation was given of an example case in which the grooves 21a are formed in the base frame 21. The present disclosure is not limited to this structure, and for example, the grooves 21a formed in the base frame 21 may be filled with a resin.

In addition, the grooves 21a formed in the base frame 21 may be filled with a metal. In this case, it is preferable that a metal with a thermal expansion rate which is larger than that of silicon (Si) forming the semiconductor chip 22, and which is smaller than that of copper (Cu) forming the base frame 21 should be applied. For example, nickel (Ni) or tungsten (W) may be applied to the grooves 21a formed in the base frame 21. By filling a metal in the grooves 21a, the thermal conductivity per a unit area between the semiconductor chip 22 and the base frame 21 can be improved. Accordingly, it becomes possible to suppress an increase of stress produced between the semiconductor chip 22 and the base frame 21, and to efficiently dissipate heat from the semiconductor chip 22.

In the above embodiment, as illustrated in FIG. 6, the relative position of the wafer 220 and those of the circuit patterns 221 are adjusted in such a way the arrangement direction (X-axis direction or Y-axis direction) of the circuit patterns 221 formed on the wafer 220 forms an angle of 45 degrees relative to the grooves 211 formed in the copper plate 210. The present disclosure is not limited to this structure, and the angle between the arrangement direction (X-axis direction or Y-axis direction) of the circuit patterns 221 and the grooves 211 may be, for example, 30 degrees or 60 degrees. In fact, the angle between the arrangement direction (X-axis direction or Y-axis direction) of the circuit patterns 221 and the grooves 211 can be set freely as long as the arrangement direction (X-axis direction or Y-axis direction) of the circuit patterns 221 is not in parallel with the grooves 211.

In the above embodiment, as illustrated in FIG. 12, the outer circumference of the rectangular semiconductor chip 22 in parallel with the X-axis and the other outer circumference in parallel with the Y-axis form an angle of 45 degrees relative to the grooves. The present disclosure is not limited to this structure, and the angle between the outer circumference of the semiconductor chip 22 and the grooves can be set freely as long as the outer circumferences of the semiconductor chip 22 are not in parallel with the grooves.

In the above embodiment, the explanation was given of an example case in which, as illustrated in FIG. 5, the grooves 211 in parallel with the X-axis and the grooves 211 in parallel with the Y-axis are formed in a surface of the copper plate 210 so as to be orthogonal one another. It is preferable that the grooves 211 formed in the copper plate 210 should intersect with each other when those grooves are not orthogonal one another. In addition, only the grooves 211 in parallel with the X-axis or the grooves 211 in parallel with the Y-axis may be formed in the copper plate 210.

In the above embodiment, the explanation was given of an example case in which, as illustrated in FIG. 12, the grooves 21a orthogonal one another are formed in the top face of the base frame 21. The present disclosure is not limited to this structure, and only the grooves 21a in parallel one another may be formed in the base frame 21. In addition, the grooves 21a not orthogonal one another but intersecting one another may be formed in the base frame 21.

In the above embodiment, the wafer 220 and the copper plate 210 were cut using the dicing blades. The present disclosure is not limited to this example case, and the wafer 220 and the copper plate 210 may be cut by laser beam. In this case, stealth dicing may be performed to cut the wafer 220.

In the above embodiment, the explanation was given of an example case in which the semiconductor package 10 is a QFN type semiconductor package. The present disclosure is not limited to this case, and for example, the semiconductor package 10 may be the semiconductor package other than the QFN type, such as a QFP (Quad Flat Package) type semiconductor package.

In the above embodiment, the explanation was given of an example case in which the base frame 21 is formed of copper. The present disclosure is not limited to the case, and for example, the base frame 21 may be formed of low-resistance metal like aluminum.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor package comprising:
a frame formed of a metal and comprising a plurality of grooves formed in a surface; and
a semiconductor chip connected with the surface of the frame.

2. The semiconductor package according to claim 1, wherein some of the grooves are formed so as to be in parallel with a first axis that is in parallel with the surface of the frame, and others of the grooves are formed so as to be in parallel with a second axis that intersects with the first axis.

3. The semiconductor package according to claim 1, wherein the grooves are formed in a direction of the first axis and in a direction of the second axis at a pitch shorter than a width of the semiconductor chip.

4. The semiconductor package according to claim 1, wherein the grooves are filled with a metal that has a thermal expansion rate which is larger than a thermal expansion rate of the semiconductor chip and which is smaller than a thermal expansion rate of the frame.

5. The semiconductor package according to claim 2, wherein the first axis and the second axis are orthogonal to each other.

6. The semiconductor package according to claim 1, wherein an outer circumference of the semiconductor chip intersects with the grooves of the frame.

7. The semiconductor package according to claim 1, wherein an outer circumference of the semiconductor chip forms an angle of 45 degrees relative to the grooves of the frame.

8. The semiconductor package according to claim 1, further comprising:
terminals disposed around the frame; and
wires connecting the respective terminals with the semiconductor chip.

9. The semiconductor package according to claim 8, further comprising a resin that molds the wires.

10. The semiconductor package according to claim 1, wherein the semiconductor package is a QFN type package.

11. The semiconductor package according to claim 1, wherein the frame is formed of copper.

12. The semiconductor package according to claim 1, wherein the frame and the semiconductor chip are bonded together by surface activation.

13. A method of manufacturing a semiconductor package, the method comprising steps of:
bonding, by surface activation, a silicon substrate to a surface of a metal plate, wherein grooves are formed in the surface; and
cutting the silicon substrate together with the metal plate to cut out a semiconductor device.

14. The semiconductor package manufacturing method according to claim 13, wherein the step of cutting out the semiconductor device comprises:
a first dicing step of cutting the metal plate by a first dicing blade; and
a second dicing step of cutting the silicon substrate by a second dicing blade that is thinner than the first dicing blade.

15. The semiconductor package manufacturing method according to claim 13, further comprising a step of positioning the silicon substrate relative to the metal plate in such a way that an arrangement direction of circuit patterns formed on the silicon substrate intersect with the grooves of the metal plate.

16. The semiconductor package manufacturing method according to claim 13, further comprising a step of positioning the silicon substrate relative to the metal plate in such a way that an arrangement direction of circuit patterns formed on the silicon substrate forms an angle of 45 degrees relative to the grooves of the metal plate.
